(19) United States
(12) Patent Application Publication
(10) Pub. No.: US 2007/0256731 A1
(43) Pub. Date: Nov. 8, 2007

(54) Gel Electrolyte Precursor for Use in a Dye-Sensitized Solar Cell and Dye-Sensitized Solar Cell

(75) Inventor: Shuzi Hayase, Fukuoka (JP)

Correspondence Address: KRATZ, QUINTOS & HANSON, LLP, 1420 K Street, N.W., Suite 400, WASHINGTON, DC, 20005, US

(73) Assignee: NATIONAL UNIVERSITY CORPORATION KYUSHU INSTITUTE OF TECHNOLOGY, KITAKYUSHU-SHI (JP)

(21) Appl. No.: 11/659,494

(22) PCT Filed: Jul. 7, 2005
(86) PCT No.: PCT/JP05/12540

§ 371 Date: Feb. 6, 2007

(30) Foreign Application Priority Data
Aug. 17, 2004 (JP) 2004-236901

(51) Int. Cl. H01L 31/00

(52) U.S. Cl. 136/252

(57) ABSTRACT

The present invention is intended to provide a gel electrolyte precursor for use in a dye-sensitized solar cell which is easy to handle when used to fabricate solar cells and provides a solar cell excellent in photoelectric conversion efficiency and to provide dye-sensitized solar cells. Dye-sensitized solar cell 10 is made up of: an electrode consisting of transparent substrate 12a with transparent conductive film 14a and metal oxide semiconductor layer 16 deposited on its surface and sensitizing dye layer 18 supported thereon; and an electrode consisting of transparent glass plate 12b with transparent conductive film 14b deposited on its surface and a good-conducting metal sputter-deposited thereon, wherein between the two electrodes a closed space is defined by separator 20, and electrolyte layer 22, which is a gelled electrolysis solution, is arranged in the closed space. Electrolyte layer 22 is prepared by arranging, between the electrodes, an electrolysis solution with a crosslinkable precursor mixed therein and allowing the crosslinkable precursor to react and crosslink so that the electrolysis solution is gelled. The crosslinkable precursor is a gel electrolyte precursor and is composed of inorganic particles and an organic substance which reacts with the inorganic particle surface when heated, or of two or more kinds of organic substances which react when heated.

### TECHNICAL FIELD

The present invention relates to a gel electrolyte precursor for use in a dye-sensitized solar cell and a dye-sensitized solar cell, in particular, to a technique for gelling an electrolysis solution used in dye-sensitized solar cells.

### BACKGROUND ART

Dye-sensitized solar cells are referred to as wet solar cells or Graetzel cells and are characterized in that they use no silicon semiconductor and have an electrochemical cell structure typically of an iodine solution. Specifically, they have a simple structure made up of: an electrode (titania layer), which is prepared by burning titanium dioxide powder on the surface of a transparent conductive glass plate and allowing the titanium oxide powder to adsorb dye molecules; a counter electrode of a conductive glass plate; and an iodine solution, as an electrolysis solution (electrolyte layer), arranged between the two electrodes.

Dye-sensitized solar cells have attracted considerable attention as low-cost solar cells because their raw materials are inexpensive and their fabrication does not require large-scale equipment.

In achieving practical use of such dye-sensitized solar cells, however, the problem of decrease in photoelectric conversion efficiency, due to leakage and vaporization of the electrolysis solution (hereinafter sometimes referred to as electrolyte layer), still remains unsolved.

To solve this problem, the solidification of the electrolyte layer has been studied.

For example, there is proposed a process in which a mixture of a polysiloxane derivative precursor having a hydrosilyl group and an electrolysis solution is injected between two electrodes and heated to give a gel electrolyte layer (Japanese Patent Laid-Open No. 2002-216861).

There is reported, in connection with the above process, a process in which silica-based particles are mixed into the electrolysis solution to enhance the ion diffusion of the same, thereby improving the photoelectric conversion efficiency (Japanese Patent Laid-Open No. 2004-178885).

However, there still remains, in the above processes, a problem of the gel electrolyte being difficult to impregnate into the titania layer, because the gel electrolyte has a high initial viscosity for the former process (Japanese Patent Laid-Open No. 2002-216861) and the gel electrolyte is substantially in the gel form when injected between the electrodes for the latter process (Japanese Patent Laid-Open No. 2004-178885).

On the other hand, there is proposed a process in which a crosslinked gel polymer, which is prepared by injecting between a pair of electrodes an electrolysis solution consisting of a crosslinkable substance, a solvent and redox system constituting substances, and a solvent for dissolving these substances and causing polymerization in the electrolysis solution, is used as an electrolyte layer (Japanese Patent Laid-Open No. 2001-85075).

The patent specification states that use of the process makes it possible to overcome the problem of decrease in photoelectric conversion efficiency, which is caused by the increase in interface resistance between the electrodes and the electrolyte caused when a solid electrolyte is used.

The above process, in which a crosslinked gel polymer is used as an electrolyte layer, however, actually has a problem pertinent to the process that it is necessary to form a gel in a solvent containing no electrolyte and then to replace the electrolysis solution, because iodine which is widely used as an electrolyte inhibits the radical polymerization.

There are also proposed processes, as described below, in which like the above process (Japanese Patent Laid-Open No. 2001-85075), an electrolysis solution is substantially gelled in state where it is injected between the electrodes, in other words, a gel electrolyte precursor is used.

There is proposed a process in which first, a raw material capable of having a network structure, for example, a raw material that contains an organic silicon compound having a hydroxyl group bound to a silicon atom and a raw material that is composed of an electrolyte containing iodine are prepared separately, then the raw materials are mixed immediately before they are injected between the electrodes, if necessary, together with a crosslinking material to give an electrolysis solution, and if necessary, the electrolysis solution is heated in state where it is injected between the electrodes so that it is substantially gelled (Japanese Patent Laid-Open No. 2003-17147).

The patent specification states that the electrolysis solution can be gelled in state where it is injected between the electrodes, because the mixing of an electrolyte containing iodine with such an organic silicon compound makes it possible to form a siloxane bond by dehydrative condensation reaction.

There is also provided a process in which an electrolyte composition of a polymer capable of being gelled by mixing, etc. is mixed immediately before or immediately after injection between the electrodes (Japanese Patent Laid-Open Nos. 2003-86258, Laid-Open No. 203520)

However, in any of the above described conventional processes using a gel electrolyte precursor, the storage and control of raw materials is complicated because two types of raw materials, which are to be gelled by mixing with each other, are stored and controlled separately and are mixed when injected between the electrodes.

Further, in any of the above described conventional processes using a gel electrolyte precursor, the mixture of the materials is susceptible to gelation, although one is more likely to be gelled than the others, and thus, the inevitable result is that the gelation progresses to some extent during the arrangements inevitably needed between the time when mixing the raw materials and the time when injecting the mixed materials between the electrodes. This makes complicated the operations of injecting the gel electrolyte precursor between the electrodes and allows to remain the problem of the gel electrolyte being hard to impregnate into the titania layer.

The present invention has been made in the light of the above described problems. Accordingly, an object of the present invention is to provide a gel electrolyte precursor for use in a dye-sensitized solar cell which is easy to handle when used to fabricate solar cells and provides solar cells excellent in photoelectric conversion efficiency and to provide a dye-sensitized solar cell.

### DISCLOSURE OF THE INVENTION

To achieve the above object, the gel electrolyte precursor for use in a dye-sensitized solar cell according to the present invention is characterized in that it contains two or more compounds which react when heated and at least one of which is in the dispersed state, along with an iodine redox electrolyte and it is gelled by the above reaction.

The gel electrolyte precursor for use in a dye-sensitized solar cell according to the present invention is characterized in that the compound in a dispersed state is inorganic particles.

The dye-sensitized solar cell according to the present invention is characterized in that it contains an electrolyte layer prepared using the above gel electrolyte precursor for use in a dye-sensitized solar cell.

The gel electrolyte precursor for use in a dye-sensitized solar cell according to the present invention contains two or more compounds which react with an iodine redox electrolyte when heated and at least one of which is in the dispersed state and is gelled by the reaction with the iodine redox electrolyte, whereby the gel electrolyte precursor is easy to store and control, the low-viscosity electrolyte is easy to inject between a pair of electrodes, and the electrolysis solution precursor is easy to handle when used to fabricate solar cells.

Further, the electrolysis solution is easy to impregnate into the pores of the electrodes, whereby the photoelectric conversion efficiency of dye-sensitized solar cells which include an electrolyte layer prepared using the above gel electrolyte precursor can be improved.

### BRIEF DESCRIPTION OF THE DRAWINGS

FIG. 1 is a schematic cross-sectional view of a dye-sensitized solar cell of the present invention.

### DESCRIPTION OF REFERENCE NUMERAL

10 Dye-sensitized solar cell
12a, 12b Transparent substrate
14a, 14b Transparent conductive film
16 Metal oxide semiconductor layer
18 Sensitizing dye layer
20 Separator
22 Electrolyte layer

### BEST MODE FOR CARRYING OUT THE INVENTION

In the following the embodiments of the present invention will be described.

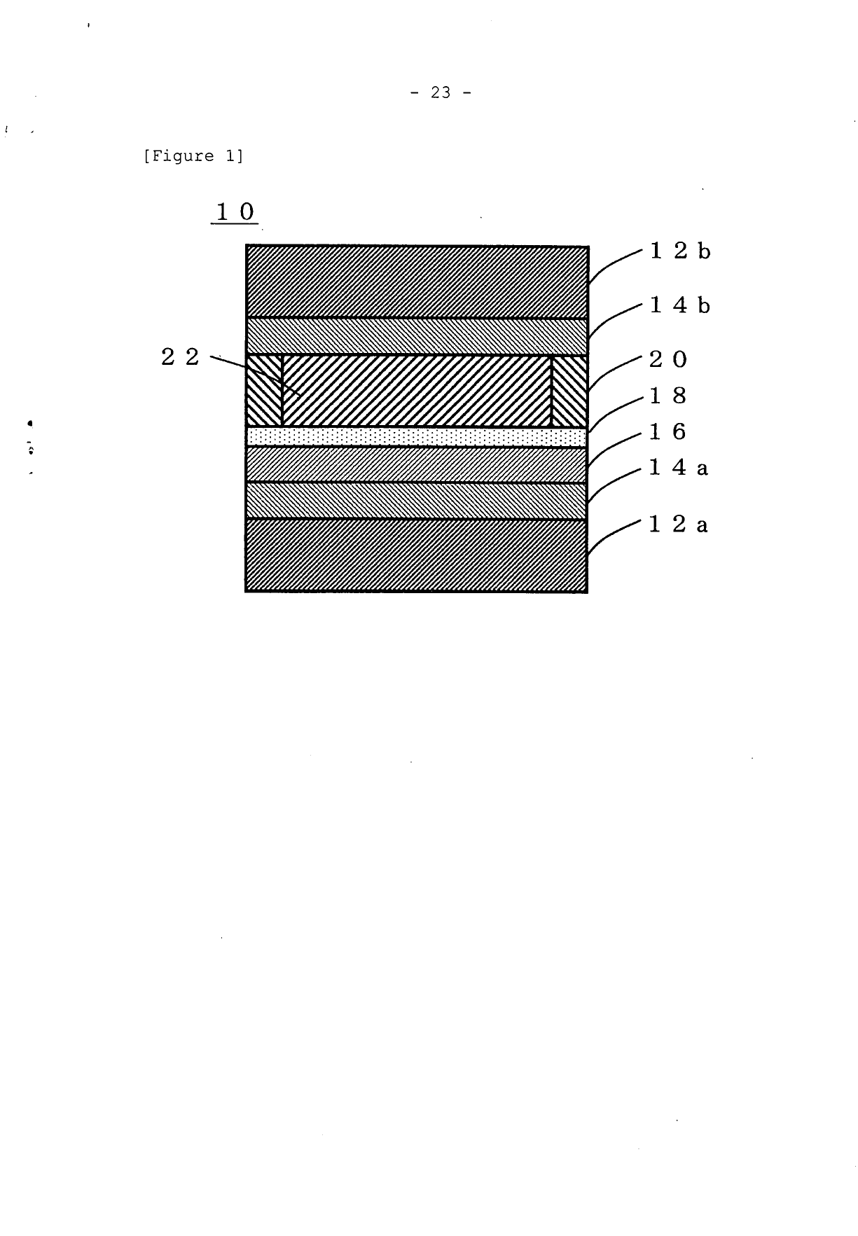

One example of the configurations of the dye-sensitized solar cells (hereinafter sometimes referred to as simply cells) of the present invention is shown in FIG. 1.

FIG. 1 is a schematic cross-sectional view of a cell. In the figure, cell 10 includes a pair of transparent substrates 12a, 12b opposite to each other. On transparent substrate 12a, transparent conductive film 14a and metal oxide semiconductor layer 16 are deposited in this order. On metal oxide semiconductor layer 16, sensitizing dye layer 18 is supported. Thus, one electrode is made up. On transparent glass plate 12b, transparent conductive film 14b is deposited. On transparent conductive film 14b, a good-conducting metal is sputter-deposited (not shown in the figure). Thus, the other electrode (counter electrode) is made up.

Between the two electrodes, more precisely, between metal oxide semiconductor layer 16 and transparent conductive film 12b, separator 20 is inserted so that closed space is defined. In the closed space, electrolyte layer 22 prepared by gelling an electrolysis solution is arranged.

For the constituents, other than electrolyte 22, of cell 10, their types are not limited to specific ones, and they can be properly selected from those commonly used and the film thickness can also be properly selected.

Transparent substrates 12a, 12b may be, for example, either glass plates or plastic plates.

Transparent conductive films 14a, 14b may be, for example, either ITO or SnO₂.

For metal oxide semiconductor layer 16, for example, titanium, tin, zirconium, zinc, indium, tungsten, iron, nickel or silver may be used as a metal.

As a dye for sensitizing dye layer 18, for example, a metal or non-metal, such as a transition metal complex of ruthenium, or phthalocyanine or porphine, may be used.

As a good-conducting metal to be sputter-deposited, for example, a substance which is not corroded by iodine, such as platinum, a conductive polymer or carbon, or gold can be used.

Electrolyte layer 22 is a gel form of an electrolysis solution prepared by injecting and arranging an electrolysis solution with a crosslinkable precursor mixed thereinto, in other words, a gel electrolyte precursor between a pair of electrodes and then allowing the crosslinkable precursor to react and crosslink.

The crosslinkable precursor is a component (compound) which does not react at ordinary temperature but does react to crosslink when heated, when it is in the form of a mixture with a solution of an electrolyte (a electrolysis solution) containing a redox substance. To stabilize at ordinary temperature, one of the cross linking agents reactive each other is phase-separated from or dispersed in the electrolysis solution.

When it is intended to phase-separate one of the crosslinking agents from the electrolysis solution after gelation, solubility change caused with the phase change in molecular structure is used. In this case, reversible phase separation of gel electrolyte layer 22 occurring during the use of the cell might affect the performance of the cell; however, according to the present invention, phase separation is less likely to affect the performance of the cell.

When it is intended to disperse one of the crosslinking agents in the electrolysis solution, a crosslinking agent in the form of particles which does not react with the electrolysis solution at ordinary temperature may also be used.

Heating of the crosslinkable precursor already injected between a pair of electrodes makes its uniform dissolution and rapid gelation possible. The reaction temperature when the crosslinkable precursor is heated differs depending on the crosslinking temperature of the component used; however, it is at least sufficiently higher than the atmospheric temperature at which cells are fabricated, such as ordinary temperature, and sufficiently low not to cause damage by heat in the other structures of the cell. The reaction temperature is, for example, around 80° C.

This makes it possible to handle the electrolysis solution in the low-viscosity and high-flowability state, whereby the electrolysis solution can be injected into the closed space between a pair of electrodes easily and properly when fabricating cell 10. Further, the electrolysis solution can be fully impregnated into the pores of metal oxide semiconductor layer 16.

As such a crosslinkable precursor, (1) one consisting of inorganic particles and an organic substance that reacts with the surface of the inorganic particles when heated or (2) one consisting of at least two or more kinds of organic substances that react when heated can be used.

In the case of the crosslinkable precursor (1), as inorganic particles, suitably used is, but not limited to, nano-size silica. Besides nano-size silica, inorganic particles of, for example, titania, zinc oxide, tin oxide or alumina can also be used. Further, inorganic particles, as described above, with their surface covered with an organic group reactive with a carboxylic acid, for example, a base such as pyridine can also be used.

As an organic substance that reacts with the surface of inorganic particles when heated, suitably used are, but not limited to, dicarboxylic acids having a high molecular weight (HOOC(CH₂)nCOOH(n=10-50)), polymers of monocarboxylic acids and other carboxylic acids. Examples of these acids include: hexadecanedioic acid (DDA), dodecanedioic acid (DDA), docosanedioic acid, dodecanedicarboxylic acid, undecanedicarboxylic acid, undecanedioic acid, sebacic acid, azelaic acid, pimelic acid, oxalic acid, poly(oligo)acrylic acid and the copolymer thereof, benzophenonetetracarboxylic acid, diphenylsulfonetetracarboxylic acid, benzophenonetricarboxylic acid and benzophenonedicarboxylic acid.

As a dicarboxylic acid having a high molecular weight, onewith 10 to 20 carbonatoms is suitablyused from theviewpoint of phase separation.

In the case of the crosslinkable precursor (2), as one of at least two or more kinds of organic substances that react when heated, any of the carboxylic acids shown in connection with the above crosslinkable precursor (1) can be suitably used. As the other organic substance, suitably used are, but not limited to, nitrogen-containing compounds reactive with a carboxylic acid, such as polyvinylpyridine, polyvinylimidazole, pyridine and compounds containing 2 or more imidazoles per molecule.

As a redox substance which is the electrolyte of electrolyte layer 22, suitably used are, but not limited to, the combination of iodide ion and iodine. Specifically, the combination of a metal iodide, such as LiI, NaI or CaI₂, and iodine can be used. Examples of other combinations include: bromide ion-bromine, thallium ion (III)-thallium ion (I) and mercury ion (II)-mercury ion (I).

In the dye-sensitized solar cells of the present invention, the electrolyte solution is stored with two or more kinds of reactive substances dispersed therein, whereby the operation of injecting the electrolyte solution between a pair of electrodes, when fabricating cells, can be easily and reliably performed, and the electrolyte solution can be gelled in a short period of time by heating the solution after injection to allow the reactive substances to react and crosslink.

In the dye-sensitized solar cells of the present invention, since the electrolyte solution, whose reaction at room temperature (ordinary temperature) is fully suppressed, is solidified after it is sufficiently impregnated into the pores of the metal oxide semiconductor layer, the electrolyte and the metal oxide semiconductor layer can be brought into full contact with each other, whereby the photoelectric conversion efficiency can be improved.

The technique for gelling an electrolyte solution according to the present invention is applicable not only to dye-sensitized solar cells, but to a wide variety of photoelectric converters such as optical sensors and light receiving elements.

### EXAMPLES

In the following the present invention will be further described giving several examples and comparative examples. It is to be understood that these examples are for illustrative purpose only and not intended to limit the present invention.

### Example 1

A transparent substrate (manufactured by Nippon Sheet Glass, 30 ohm/≡) with a transparent conductive film consisting of SnO₂ vacuum-deposited on its surface was coated with D paste (trade name: Ti-Nanoxide D) manufactured by Solaronix and baked at 450° C. for 30 minutes to prepare a titania electrode (titanium dioxide semiconductor layer). Besides this electrode, a transparent substrate with a transparent conductive film containing platinum deposited on its surface was prepared as a counter electrode. These two electrodes were fabricated into a cell using 50-micron HIMILAN (registered trademark, resin manufactured by Du Pont—Mitsui Polychemicals) as spacers and adhesive.

On the other hand, the iodine-based electrolysis solution (electrolyte solution) having the composition shown in Table 1 was mixed with crosslinking agent A and crosslinking agent B shown in Table 1 at room temperature to prepare a low-viscosity and uniformly dispersed electrolysis solution. In Table 1, crosslinking agent A used in Example 1 was silica fine particles, “50 (3 wt %)” means that 3% by mass of product manufactured by Nippon Aerosil (product number 50), as crosslinking agent A, was mixed into the electrolysis solution, and “3%” of crosslinking agent B means that 3% by mass of crosslinking agent B was mixed into the electrolysis solution. The same is true for the other examples. The denotations, 300, OX50 and R805 of crosslinking agent A also represent the product numbers of the products manufactured by Nippon Aerosil.

After poured into the cell through the spacing between the spacers, the electrolysis solution was heated at 80° C. for one minute. Thus, a dye-sensitized solar cell was fabricated in which the electrolysis solution had been solidified.

The evaluation of the fabricated dye-sensitized solar cell for the solar cell efficiency (photoelectric conversion efficiency) made at AM −1.5 and 100 mW/cm² was shown in Table 1.

TABLE 1

| | Ex. 1 | Ex. 2 | Ex. 3 | Ex. 4 | Ex. 5 | Ex. 6 | Ex. 7 | Ex. 8 |
|---|---|---|---|---|---|---|---|---|
| Crosslinking agent A | 50 (3 wt %) | 50 (6 wt %) | 300 (1 wt %) | 300 (2 wt %) | Ox50 (3 wt %) | OX50 (6 wt %) | OX50 (9%) | R805 (1 wt %) |
| Crosslinking agent B | DDA (3%) | HDDA (4%) | DDA (3%) | HDDA (4%) | DDA (3%) | HDDA (4%) | HDDA (4%) | DDA (3%) |
| Crosslinking agent C | | | | | | | | |
| State of crosslinking | Dispersed | Dispersed | Dispersed | Dispersed | Dispersed | Dispersed | Dispersed | Dispersed |
| agent A after mixing | | | | | | | | |
| State of crosslinking | Dispersed | Dispersed | Dispersed | Dispersed | Dispersed | Dispersed | Dispersed | Dispersed |
| agent B after mixing | | | | | | | | |
| State of crosslinking | | | | | | | | |
| agent C after mixing | | | | | | | | |
| State after mixing | Low- | Low- | Low-viscosity | Low- | Low- | Low- | Low- | Low- |
| | viscosity | viscosity | liquid | viscosity | viscosity | viscosity | viscosity | viscosity |
| | liquid | liquid | | liquid | liquid | liquid | liquid | liquid |
| State after heating at | Gel | Gel | Gel | Gel | Gel | Gel | Gel | Gel |
| 80° C. for 1 min | | | | | | | | |
| Efficiency (%) | 6.0 | 5.5 | 5.3 | 5.8 | 4.8 | 5.2 | 5.3 | 4.6 |
| Number of days required | 5 days or | 5 days or | 5 days or | 5 days or | 5 days or | 5 days or | 5 days or | 5 days or |
| for viscosity to double | longer | longer | longer | longer | longer | longer | longer | longer |
| at room temperature | | | | | | | | |

Electrolysis solution used: Methylpropylimidazolium iodide Iodine 300 mM, LiI 500 mM, t-butylpyridine 580 mM
Crosslinking agent A: Nano-particle (inorganic) manufactured by Nippon Aerosil
Crosslinking agent B: HDDA: hexadecanedioic acid, DDA: dodecanedioic acid, AA: adipic acid (organic crosslinking agent)
Crosslinking agent C: PVP polyvinylpyridine (organic crosslinking agent)

### Comparative Examples 1 to 3

Cells were fabricated in the same manner as in Example 1 using an electrolysis solution containing no crosslinking agent, an electrolysis solution containing crosslinking agent A alone, and an electrolysis solution containing crosslinking agent B alone.

The results are shown in Table 2. In the dye-sensitized solar cells of Comparative Examples 1 to 3, none of the electrolysis solutions were gelled even after heating at 80° C. for 1 minute.

This indicates that to gel electrolysis solutions, both crosslinking agents A and B are indispensable. The results support the usefulness of the present invention.

TABLE 2

| Ex. 9 | Ex. 10 | Com. Ex. 1 | Com. Ex. 2 | Com. Ex. 3 | Com. Ex. 4 |
|---|---|---|---|---|---|
| | | None | 50 (3 wt %) | | 50 (3 wt %) |
| HDDA (3%) | HDDA (3%) | None | | DDA (3%) | AA (3%) |
| PVP (3%) | PVP (3%) | | | | |
| | | None | Dispersed | | Dispersed |
| Dispersed | Dispersed | None | | Dispersed | Uniform |
| Dispersed | Uniform | | | | |
| Low-viscosity | Low-viscosity | Low-viscosity | Low-viscosity | Low-viscosity | Low-viscosity |
| liquid | liquid | liquid | liquid | liquid | liquid |
| Gel | Gel | Low-viscosity | Low-viscosity | Low-viscosity | Precipitated |
| | | liquid | liquid | liquid | |
| 4.3 | 4.3 | 4.0 | 4.1 | 4.2 | 6.0 |
| 5 days or | 5 days or | 5 days or | 5 days or | 5 days or | 1 minute |
| longer | longer | longer | longer | longer | |

### Examples 2 to 8

Cells were fabricated in the same manner as in Example 1 using electrolysis solutions containing crosslinking agents A and B.

The results are shown in Table 1. In any of the dye-sensitized solar cells of Examples 2 to 8, the electrolysis solutions were gelled. The dye-sensitized solar cells all showed an excellent solar cell efficiency compared with those before gelation, though the numerical values are not shown. The electrolysis solutions before heating all excelled in storage stability at room temperature, and even after 5-day storage, the viscosity did not reach two times the initial viscosity. These results demonstrate the gel solidification, the storage stability at room temperature of the gel electrolyte precursors and the solar cell characteristics and support the usefulness of the present invention.

### Comparative Example 4

A cell was prepared in the same manner as in Example 1 using an electrolysis solution in which AA of crosslinking agent B was completely dissolved and then particles of product number 50 were dispersed.

The results are shown in Table 2. In the dye-sensitized solar cell of Comparative Example 4, a precipitate was formed during mixing the electrolysis solution and gelation did not take place. This is because the crosslinking agents reacted with each other so rapidly that uniform gel could not be formed.

### Example 9

A cell was prepared in the same manner as in Example 1 using an electrolysis solution containing dispersion of crosslinking agent B and that of crosslinking agent C shown in Table 2.

The results are shown in Table 2. In the dye-sensitized solar cell of Example 9, the electrolysis solution was gelled. The dye-sensitized solar cell showed an excellent solar cell efficiency compared with that before gelation, though the numerical values are not shown. The electrolysis solution before heating excelled in storage stability at room temperature, and even after 5-day storage, the viscosity did not reach two times the initial viscosity. These results demonstrate the gel solidification, the storage stability at room temperature of the gel electrolyte precursor and the solar cell characteristics and support the usefulness of the present invention.

### Example 10

A cell was prepared in the same manner as in Example 1 using an electrolysis solution containing crosslinking agent B and a uniform solution of crosslinking agent C.

The results are shown in Table 2. In the dye-sensitized solar cell of Example 9, the electrolysis solution was gelled. The dye-sensitized solar cell showed a good performance compared with that before gelation, though the numerical values are not shown. The electrolysis solution before heating excelled in storage stability at room temperature, and even after 5-day storage, the viscosity did not reach two times the initial viscosity. These results demonstrate the gel solidification, the storage stability at room temperature of the gel electrolyte precursor and the solar cell characteristics and support the usefulness of the present invention.

### Comparative Example 5

Silicon resin having hydroxyl group, SH6018 (manufactured by Toray Silicone), was dissolved in methylpropylimidazolium iodide, and 300 mM of iodine, 500 mM of LiI and 580 mM of t-butylpyridine were added. After allowed to stand at room temperature for 1 day, the mixture was gelled.

1. A gel electrolyte precursor for use in a dye-sensitized solar cell, characterized in that it comprises two or more compounds which are phase-separated from each other at ordinary temperature and react with each other to crosslink when heated, along with an iodine redox electrolyte and it is gelled by the reaction.

2. The gel electrolyte precursor for use in a dye-sensitized solar cell according to claim 1, characterized in that one of said two or more compounds is inorganic particles.

3. (canceled)

4. The gel electrolyte precursor for use in a dye-sensitized solar cell according to claim 1, characterized in that one of said two or more compounds is a carboxylic acid.

5. A dye-sensitized solar cell, comprising an electrolyte layer prepared using the gel electrolyte precursor for use in a dye-sensitized solar cell according to any one of claims 1, 2 and 4.
